(19) United States
(12) Patent Application Publication
(10) Pub. No.: US 2021/0343553 A1
(43) Pub. Date: Nov. 4, 2021

(54) SEMICONDUCTOR EQUIPMENT AND METHOD FOR MANUFACTURING SEMICONDUCTOR STRUCTURE

(71) Applicant: CHANGXIN MEMORY TECHNOLOGIES, INC., Hefei City (CN)

(72) Inventor: Xun YAN, Hefei (CN)

(21) Appl. No.: 17/376,601

(22) Filed: Jul. 15, 2021

Related U.S. Application Data
(63) Continuation of application No. PCT/CN2021/083116, filed on Mar. 26, 2021.

(30) Foreign Application Priority Data
Mar. 31, 2020 (CN) 202010245810.9

(51) Int. Cl. H01L 21/67; H01L 21/3065

(52) U.S. Cl. CPC H01L 21/67069; H01L 21/3065

(57) ABSTRACT

The present application relates to semiconductor equipment and a method for manufacturing a semiconductor structure. The semiconductor equipment includes: a process chamber for processing a wafer; a gas intake apparatus, configured to introduce gas into the process chamber; and a gas distribution plate, located above the wafer and on a flow path of the gas; and at least part of the gas flows to a surface of the wafer through the gas distribution plate.

### CROSS-REFERENCE TO RELATED APPLICATIONS

The present application is a U.S. continuation application of International Application No. PCT/CN2021/083116, filed on Mar. 26, 2021, which claims priority to Chinese Patent Application No. 202010245810.9, filed on Mar. 31, 2020. International Application No. PCT/CN2021/083116 and Chinese Patent Application No. 202010245810.9 are incorporated herein by reference in their entireties.

### TECHNICAL FIELD

The present application relates to the field of semiconductor manufacture, and more particularly, to semiconductor equipment and a method for manufacturing a semiconductor structure.

### BACKGROUND

Photoetching is a process for removing specific portions of a thin film on a surface of a wafer through a series of production steps. Afterwards, a thin film of a micropattern structure is left on the surface of the wafer. Through the photoetching process, a feature pattern is retained on the wafer at last. The general photoetching process includes silicon wafer surface cleaning and drying, precoating, photoresist spin coating, soft baking, alignment and exposure, postbaking, developing, hard baking, etching, detection, etc. However, a central region and an edge region of the wafer are typically inconsistent in feature size, which seriously affects the yield of the device and results in difficulty in adjusting the process parameters.

### SUMMARY

According to various examples of the present application, semiconductor equipment and a method for manufacturing a semiconductor structure are provided.

The present application provides semiconductor equipment, which may include: a process chamber for processing a wafer; a gas intake apparatus, configured to introduce gas into the process chamber; and a gas distribution plate, located above the wafer and on a flow path of the gas; and at least part of the gas flows to a surface of the wafer through the gas distribution plate.

According to the above semiconductor equipment, the gas distribution plate can make a flow velocity of the gas on the surface of the wafer uniform, and make a temperature on the surface of the wafer uniform, such that a temperature difference between a central region and an edge region on the surface of the wafer is reduced, and thus the line width of a pattern structure formed by photoetching is uniform.

In an example, the gas distribution plate is parallel to the wafer.

In an example, the semiconductor equipment may include a developing device.

In an example, an orthographic projection of the gas distribution plate on the surface of the wafer at least covers the wafer.

In an example, the gas distribution plate may include a plurality of vent holes.

In an example, an area of the vent hole located in a central region of the gas distribution plate is larger than an area of the vent hole located in an edge region. The area of the vent hole located in the central region of the gas distribution plate is larger than the area of the vent hole located in the edge region, such that the flow velocity of the gas on the surface of the wafer is uniform and a flow velocity difference of the gas in the central region and the edge region of the wafer is reduced.

In an example, the vent hole may include a first vent hole, a plurality of second vent holes, a plurality of third vent holes, and a plurality of fourth vent holes. The first vent hole is located in a center of the gas distribution plate. The plurality of second vent holes are located at the periphery of the first vent hole, and arranged at intervals along a circumferential direction of the gas distribution plate. The plurality of third vent holes are located at the periphery of the second vent holes, and arranged at intervals along the circumferential direction of the gas distribution plate. The plurality of fourth vent holes are located at the periphery of the third vent holes, and arranged at intervals along the circumferential direction of the gas distribution plate. Areas of the first vent hole, the second vent hole, the third vent hole and the fourth vent hole decrease sequentially.

In an example, a shape of the first vent hole, the second vent hole, the third vent hole and the fourth vent hole may include a circular shape. The first vent hole has a radius between 7 mm and 12 mm, the second vent hole has a radius between 6 mm and 10 mm, the third vent hole has a radius between 4 mm and 6 mm, and the fourth vent hole has a radius between 2 mm and 6 mm

In an example, a plurality of gas distribution plates are provided, and the plurality of gas distribution plates are stacked in parallel and arranged at intervals. As a plurality of gas distribution plates are provided, and the plurality of gas distribution plates are stacked in parallel and arranged at intervals, the flow velocity of the gas on the surface of the wafer is uniform and the flow velocity difference of the gas in the central region and the edge region of the wafer is reduced.

In an example, a distance between adjacent gas distribution plates may be 1 cm-3 cm.

In an example, the semiconductor equipment may further include: a drive apparatus, connected to the gas distribution plate, and configured to drive the gas distribution plate to rotate. As the drive apparatus is connected to the gas distribution plate, and configured to drive the gas distribution plate to rotate, the flow velocity of the gas on the surface of the wafer is uniform and the flow velocity difference of the gas in the central region and the edge region of the wafer is reduced.

In an example, the semiconductor equipment may further include: an exhaust apparatus, communicating with the inside of the process chamber, and configured to exhaust waste gas.

The present application further provides a method for manufacturing a semiconductor structure, which may include a wafer and semiconductor equipment are provided, and the wafer is placed under the gas distribution plate; and in a process of processing the wafer, a gas is introduced into the process chamber through a gas intake apparatus, at least part of the gas flowing to a surface of the wafer through the gas distribution plate.

According to the method for manufacturing the semiconductor structure, with the use of the semiconductor equipment, the gas distribution plate can make a flow velocity of the gas on the surface of the wafer uniform, and make a temperature on the surface of the wafer uniform, such that a temperature difference between a central region and an edge region on the surface of the wafer is reduced, and thus the line width of a pattern structure formed by photoetching is uniform.

In an example, in a process of developing the wafer, the gas is introduced into the process chamber through the gas intake apparatus, at least part of the gas flowing to the surface of the wafer through the gas distribution plate.

### BRIEF DESCRIPTION OF THE DRAWINGS

The above and other objectives, features and advantages of the present application will become more apparent by describing in more detail the preferred examples of the present application shown in the accompanying drawings. The same numeral throughout the drawings represents the same part, and the drawings are not drawn by equal scaling of the actual size, with the emphasis on illustrating the tenet of the present application.

FIG. 1 is a side view of a gas distribution plate in semiconductor equipment of the present disclosure.

FIG. 2 to FIG. 3 are a top view of a gas distribution plate in semiconductor equipment of the present disclosure.

FIG. 4 is a flowchart of a method for manufacturing a semiconductor structure of the present disclosure.

### DETAILED DESCRIPTION

In order to make the above objectives, features, and advantages of the present application more obvious and understandable, the specific examples of the present application will be described in detail below in conjunction with the accompanying drawings. Numerous specific details are described in the following description in order to facilitate a thorough understanding of the present application. However, the present application can be implemented in many other modes different from those described herein. Those skilled in the art can make similar improvements without departing from the connotation of the present application. Therefore, the present application is not limited by the specific implementations disclosed hereinafter.

Unless otherwise defined, the meaning of each of the technical and scientific terms used herein is same as a general meaning understood by those skilled in the art to which the present application pertains. The terms used in the specification of the present application are merely to describe the specific examples, rather than to limit the present application. The term “and/or” used herein includes any one combination of and all possible combinations of one or more the enumerated elements.

In the description of the present application, it is understood that orientation or position relationships indicated by the terms “upper”, “lower”, “vertical”, “horizontal”, “inner”, and “outer”, and the like are based on the orientation or position relationships as shown in the drawings, for ease of describing the present application and simplifying the description only, rather than indicating or implying that the mentioned apparatus or element necessarily has a particular orientation and must be constructed and operated in the particular orientation. Therefore, these terms should not be understood as limitations to the present application.

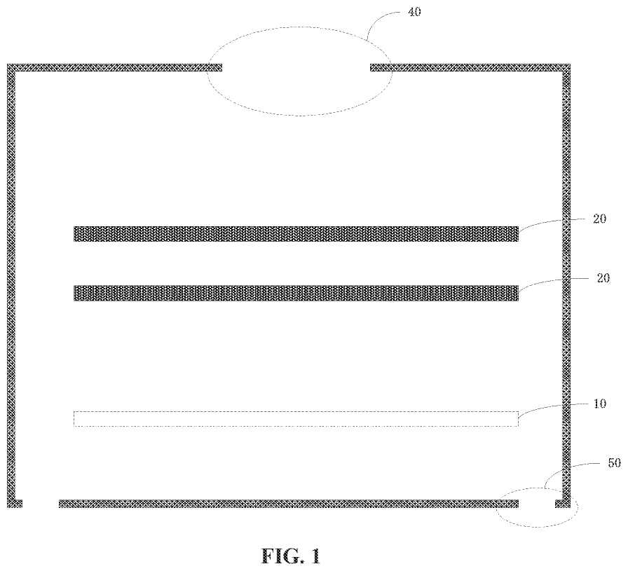

In an example, semiconductor equipment is provided, which may include: a process chamber for processing a wafer 10; a gas intake apparatus, configured to introduce gas into the process chamber; and a gas distribution plate 20, located above the wafer 10, and, as shown in FIG. 1, located on a flow path of the gas; and at least part of the gas flows to a surface of the wafer 10 through the gas distribution plate 20.

In the example, according to the above semiconductor equipment, the gas distribution plate 20 can make a flow velocity of the gas on the surface of the wafer 10 uniform, and make a temperature on the surface of the wafer 10 uniform, such that a temperature difference between a central region and an edge region on the surface of the wafer 10 is reduced, and thus the line width of a pattern structure formed by photoetching is uniform.

In an example, the gas distribution plate 20 is parallel to the wafer 10.

In an example, the semiconductor equipment may include a developing device.

A general photoetching process includes silicon wafer surface cleaning and drying, precoating, photoresist spin coating, soft baking, alignment and exposure, postbaking, developing, hard baking, etching, detection, etc. The developing device is a device for developing a photoresist.

In an example, an orthographic projection of the gas distribution plate 20 on the surface of the wafer 10 at least covers the wafer 10.

In an example, the gas distribution plate 20 may include a plurality of vent holes 30.

In an example, a middle portion of the gas distribution plate 20 is hollowed-out, and a hollowed-out pattern is not limited, all of which fall into the protection scope of the present application.

In an example, a shape of the vent hole 30 may include any shape such as a circular shape, a rectangular shape and a triangular shape.

In another example, the shape of the vent hole 30 may further include any shape such as an arc shape and a strip shape.

In an example, as shown in FIG. 3, the shape of the vent hole 30 may include the arc shape.

In an example, an area of the vent holes 30 in a central region of the gas distribution plate 20 is larger than an area of the vent holes 30 in an edge region. The area of the vent holes 30 in the central region of the gas distribution plate 20 is larger than the area of the vent holes 30 in the edge region, such that the flow velocity of the gas on the surface of the wafer 10 is uniform and a flow velocity difference of the gas in the central region and the edge region of the wafer 10 is reduced.

When the gas concentrates and rushes toward the center of the wafer 10 and flows out toward the edge of the wafer 10, the gas rushes toward the center of the wafer 10 at a flow velocity in a vertical direction, and at this time, the direction of the gas flow changes, such that the gas flows out from the center of the wafer 10 to the edge of the wafer 10. During this process, the flow velocity of the gas increases gradually such that the flow velocity at the edge of the wafer 10 is faster than that in the center of the wafer 10, thereby causing a temperature difference between the edge region and the central region of the wafer 10. By providing the gas distribution plate 20, a part of the gas directly reaches the edge region of the wafer 10 through the vent holes in the edge region of the gas distribution plate 20; and at this time, the gas can directly and uniformly rush toward the whole wafer 10 at the flow velocity in the vertical direction. After reaching the wafer 10, the gas flow flows out from the edge of the wafer 10. Although the gas in the central region still flows from the center to the edge, the velocity thereof does not increase greatly due to the impact of the vertical flow velocity of the edge gas in the process. As the gas in the edge region rushes toward the edge region of the wafer 10 at the flow velocity in the vertical direction, the flow velocity difference on the surface of the wafer 10 decreases, and thus the temperature difference on the surface of the wafer 10 is reduced.

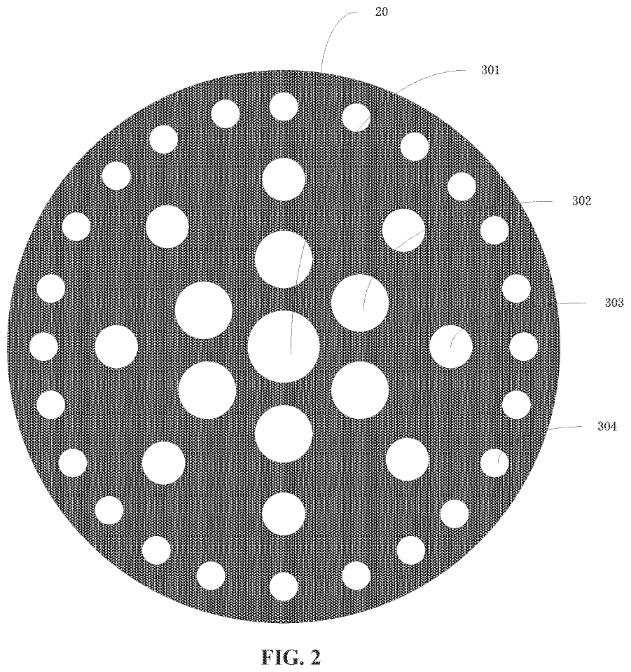

In an example, as shown in FIG. 2, the vent hole 30 may include a first vent hole 301, a plurality of second vent holes 302, a plurality of third vent holes 303, and a plurality of fourth vent holes 304. The first vent hole 301 is located in a center of the gas distribution plate 20. The plurality of second vent holes 302 are located at the periphery of the first vent hole 301, and arranged at intervals along a circumferential direction of the gas distribution plate 20. The plurality of third vent holes 303 are located at the periphery of the second vent holes 302, and arranged at intervals along the circumferential direction of the gas distribution plate 20. The plurality of fourth vent holes 304 are located at the periphery of the third vent holes 303, and arranged at intervals along the circumferential direction of the gas distribution plate 20. Areas of the first vent hole 301, the second vent hole 302, the third vent hole 303 and the fourth vent hole 304 decrease sequentially.

In the example, the plurality of second vent holes 302 are circumferentially and equidistantly arranged at intervals, the plurality of third vent holes 303 are circumferentially and equidistantly arranged at intervals, and the plurality of fourth vent holes 304 are circumferentially and equidistantly arranged at intervals.

In an example, a shape of the first vent hole 301, the second vent hole 302, the third vent hole 303 and the fourth vent hole 304 may include a circular shape. The first vent hole 301 has a radius between 7 mm and 12 mm, and preferably, the radius of the first vent hole 301 may be 10 mm The second vent hole 302 has a radius between 6 mm and 10 mm, and preferably, the radius of the second vent hole 302 may be 8 mm The third vent hole 303 has a radius between 4 mm and 6 mm, and preferably, the radius of the third vent hole 303 may be 6 mm The fourth vent hole 304 has a radius between 2 mm and 6 mm, and preferably, the radius of the fourth vent hole 304 may be 4 mm.

In an example, there may be one first vent hole 301, six second vent holes 302, eight third vent holes 303, and twenty-four fourth vent holes 304.

In an example, the gas distribution plate 20 may include any combination of more of the first vent hole 301, the second vent hole 302, the third vent hole 303, and the fourth vent hole 304.

In an example, a shape of the gas distribution plate 20 may include a circular shape, and a circle center of the gas distribution plate 20 and a circle center of the wafer 10 are aligned.

In an example, a plurality of gas distribution plates 20 are provided, and the plurality of gas distribution plates 20 are stacked in parallel and arranged at intervals. As a plurality of gas distribution plates 20 are provided, and the plurality of gas distribution plates 20 are stacked in parallel and arranged at intervals, the flow velocity of the gas on the surface of the wafer 10 is uniform and the flow velocity difference of the gas in the central region and the edge region of the wafer 10 is reduced.

In an example, there may be 1, 2, 3, 4, or more gas distribution plates 20, which is not limited herein.

In an example, a distance between adjacent gas distribution plates 20 is between 1 cm and 3 cm, and preferably, the distance between adjacent gas distribution plates 20 may be 1.5 cm.

In an example, the semiconductor equipment may further include: a drive apparatus, connected to the gas distribution plate 20, and configured to drive the gas distribution plate 20 to rotate. As the drive apparatus is connected to the gas distribution plate 20 and configured to drive the gas distribution plate 20 to rotate, the flow velocity of the gas on the surface of the wafer 10 is uniform and the flow velocity difference of the gas in the central region and the edge region of the wafer 10 is reduced.

In an example, a plurality of gas distribution plates 20 are provided, the plurality of gas distribution plates 20 are stacked in parallel and arranged at intervals, and the drive apparatus drives the gas distribution plate 20 to rotate, thereby adjusting the gas flow.

In an example, a plurality of gas distribution plates 20 are provided, the plurality of gas distribution plates 20 are stacked in parallel and arranged at intervals, and vent holes 30 on the plurality of gas distribution plates 20 are mutually staggered.

In an example, a plurality of gas distribution plates 20 are provided, the plurality of gas distribution plates 20 are stacked in parallel and arranged at intervals, and the drive apparatus drives, according to a temperature difference between the central region and the edge region on the surface of the wafer 10, the gas distribution plates 20 to rotate a certain angle, such that the vent holes 30 on the plurality of gas distribution plates 20 can be mutually staggered to some extent. Therefore, the temperature difference between the central region and the edge region on the surface of the wafer 10 can be controllably adjusted, and the state of the gas distribution plate 20 can be optimized, to improve uniformity of the temperature on the surface of the wafer.

In an example, two gas distribution plates 20 are provided, and the drive apparatus drives an upper gas distribution plate 20 to rotate, such that the flow velocity of the gas on the surface of the wafer 10 is uniform and the flow velocity difference of the gas in the central region and the edge region of the wafer 10 is reduced, and thus the temperature on the surface of the wafer is uniform.

In another example, two gas distribution plates 20 are provided, and the two gas distribution plates 20 have the same rotation direction.

In another example, two gas distribution plates 20 are provided, and the two gas distribution plates 20 have reverse rotation directions.

In another example, more than two gas distribution plates 20 are provided, and these gas distribution plates 20 have the same rotation direction.

In another example, more than two gas distribution plates 20 are provided, and adjacent gas distribution plates 20 have the reverse rotation directions.

In another example, a plurality of gas distribution plates 20 are provided, and the drive apparatus only drives an uppermost gas distribution plate 20 to rotate.

In an example, the semiconductor equipment may further include: an exhaust apparatus, communicating with inside of the process chamber, and configured to exhaust waste gas.

In an example, an exhaust port 50 of the exhaust apparatus is located under the wafer 10, and faces toward a back surface of the wafer 10.

In an example, the exhaust port 50 of the exhaust apparatus is located at a bottom edge of the process chamber.

In an example, the exhaust port 50 is located under an edge of the wafer 10.

In an example, the gas intake apparatus is located right above the wafer 10 and a gas inlet 40 faces toward the wafer 10, the gas distribution plate 20 is located between the wafer 10 and the gas intake apparatus, and a center of the gas inlet 40, a center of the gas distribution plate 20 and a center of the wafer 10 are aligned.

In another example, the gas distribution plate 20 is connected to the gas intake apparatus in one piece, and located at an air inlet of the gas intake apparatus.

In an example, a flowing direction of the gas introduced by the gas intake apparatus is perpendicular to a plane where the gas distribution plate 20 is located.

Waste gas will be produced in the developing process of the wafer 10, there is a need to introduce gas and pump out the gas, thereby exhausting the waste gas and preventing the waste gas from polluting a machine table. It is found by the inventor that if the gas is introduced in the developing process, the gas directly flowing to the surface of the wafer 10 will cause different flow velocities of the gas in the central region and the edge region of the wafer 10, such that evaporation rates of a liquid on the surface of the wafer are different and thus the temperature on the surface of the wafer 10 is not uniform. Consequently, during developing, reaction rates in the central region and the edge region of the wafer 10 are different, and the line width of a pattern structure formed by photoetching is not uniform. However, these problems are well solved by providing the gas distribution plate 20 in the present disclosure.

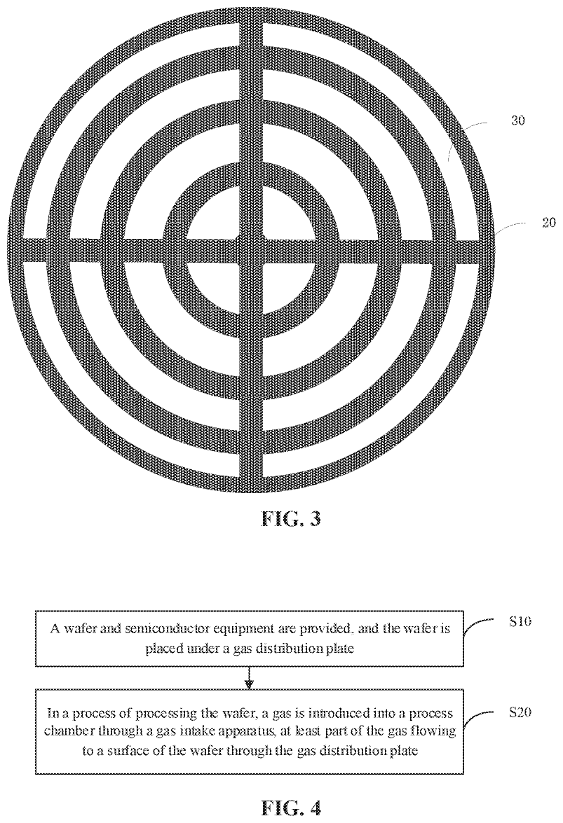

In an example, as shown in FIG. 4, a method for manufacturing a semiconductor structure is provided, which may include: a wafer 10 and semiconductor equipment are provided, and the wafer 10 is placed under a gas distribution plate 20; and in a process of processing the wafer 10, a gas is introduced into a process chamber through a gas intake apparatus, at least part of the gas flowing to a surface of the wafer 10 through the gas distribution plate 20.

In S10: a wafer 10 and semiconductor equipment are provided, and the wafer 10 is placed under a gas distribution plate 20.

In S20: in a process of processing the wafer 10, a gas is introduced into a process chamber through a gas intake apparatus, at least part of the gas flowing to a surface of the wafer 10 through the gas distribution plate 20.

In the example, according to the method for manufacturing the semiconductor structure, by using the semiconductor equipment, the gas distribution plate 20 can make a flow velocity of the gas on the surface of the wafer 10 uniform, and make a temperature on the surface of the wafer 10 uniform, such that a temperature difference between a central region and an edge region on the surface of the wafer 10 is reduced, and thus the line width of a pattern structure formed by photoetching is uniform.

In an example, in a process of developing the wafer 10, the gas is introduced to the process chamber through the gas intake apparatus, at least part of the gas flowing to the surface of the wafer 10 through the gas distribution plate 20.

The technical features of the above examples may be combined freely. In order to describe briefly, the descriptions are not made on all possible combinations of the technical features of the examples. However, the combinations of these technical features should be construed as falling into a scope of the specification as long as there is no conflict in these combinations.

The above examples only describe several implementation modes of the present application. The description is specific and detailed, but cannot be understood as limitations to a scope of the present application. It is noted that those of ordinary skill in the art can further make multiple modifications and improvements without departing from a concept of the present application and those also belong to the protection scope of the present application. Therefore, the protection scope of the present application shall only be limited by the appended claims.

1. Semiconductor equipment, comprising:
a process chamber for processing a wafer;
a gas intake apparatus, configured to introduce gas to the process chamber; and
a gas distribution plate, located above the wafer and on a flow path of the gas, at least part of the gas flowing to a surface of the wafer through the gas distribution plate.

2. The semiconductor equipment of claim 1, wherein the gas distribution plate is parallel to the wafer.

3. The semiconductor equipment of claim 1, wherein the semiconductor equipment comprises a developing device.

4. The semiconductor equipment of claim 1, wherein an orthographic projection of the gas distribution plate on the surface of the wafer at least covers the wafer.

5. The semiconductor equipment of claim 1, wherein the gas distribution plate comprises a plurality of vent holes.

6. The semiconductor equipment of claim 5, wherein an area of a vent hole in a central region of the gas distribution plate is larger than an area of a vent hole in an edge region.

7. The semiconductor equipment of claim 5, wherein the vent holes comprise a first vent hole, a plurality of second vent holes, a plurality of third vent holes, and a plurality of fourth vent holes; the first vent hole is located in a center of the gas distribution plate; the plurality of second vent holes are located at a periphery of the first vent hole, and arranged at intervals along a circumferential direction of the gas distribution plate; the plurality of third vent holes are located at a periphery of the second vent holes, and arranged at intervals along the circumferential direction of the gas distribution plate; the plurality of fourth vent holes are located at a periphery of the third vent holes, and arranged at intervals along the circumferential direction of the gas distribution plate; and areas of the first vent hole, the second vent hole, the third vent hole and the fourth vent hole decrease sequentially.

8. The semiconductor equipment of claim 7, wherein a shape of the first vent hole, the second vent hole, the third vent hole and the fourth vent hole comprises a circular shape, the first vent hole has a radius between 7 mm to 12 mm, the second vent hole has a radius between 6 mm and 10 mm, the third vent hole has a radius between 4 mm and 6 mm, and the fourth vent hole has a radius between 2 mm and 6 mm

9. The semiconductor equipment of claim 1, wherein a plurality of the gas distribution plates are provided, and the plurality of the gas distribution plates are stacked in parallel and arranged at intervals.

10. The semiconductor equipment of claim 9, wherein a distance between adjacent gas distribution plates is between 1 cm and 3 cm.

11. The semiconductor equipment of claim 1, further comprising: a drive apparatus, connected to the gas distribution plate, and configured to drive the gas distribution plate to rotate.

12. The semiconductor equipment of claim 1, further comprising: an exhaust apparatus, communicating with inside of the process chamber, and configured to exhaust waste gas.

13. A method for manufacturing a semiconductor structure, comprising:
providing a wafer and the semiconductor equipment of claim 1, and placing the wafer under the gas distribution plate; and
introducing, in a process of processing the wafer, the gas to the process chamber through the gas intake apparatus, at least part of the gas flowing to a surface of the wafer through the gas distribution plate.

14. The method for manufacturing a semiconductor structure of claim 13, wherein in a process of developing the wafer, the gas is introduced into the process chamber through the gas intake apparatus, at least part of the gas flowing to the surface of the wafer through the gas distribution plate.
